(19) United States
(12) Patent Application Publication
(10) Pub. No.: US 2022/0165970 A1
(43) Pub. Date: May 26, 2022

(54) THIN-FILM TRANSISTOR AND METHOD FOR PRODUCING A THIN-FILM TRANSISTOR

(71) Applicant: FRAUNHOFER-GESELLSCHAFT ZUR FÖRDERUNG DER ANGEWANDTEN FORSCHUNG E.V., München (DE)

(72) Inventors: Herbert A. WOLTER, Dresden (DE); Somchith NIQUE, Dresden (DE); Michael HOFFMANN, Dresden (DE); Stephanie SCHREIBER, Dresden (DE); Falk SCHÜTZE, Dresden (DE)

(73) Assignee: FRAUNHOFER-GESELLSCHAFT ZUR FÖRDERUNG DER ANGEWANDTEN FORSCHUNG E.V., München (DE)

(21) Appl. No.: 17/440,649

(22) PCT Filed: Mar. 18, 2020
(86) PCT No.: PCT/EP2020/057526

§ 371 Date: Sep. 17, 2021

(30) Foreign Application Priority Data
Mar. 20, 2019 (DE) 10 2019 107 163.1

(51) Int. Cl. H01L 51/05; H01L 51/10

(52) U.S. Cl. CPC H01L 51/055; H01L 51/105

(57) ABSTRACT

A thin-film transistor and a method for producing a thin-film transistor are provided. The thin-film transistor comprising at least one semiconductor layer, at least one insulator layer, at least one source electrode, at least one drain electrode and at least one gate electrode, which are arranged on a substrate, wherein the at least one source electrode and/or the at least one drain electrode and/or the at least one gate electrode consist(s) of a layer system comprising a first layer composed of molybdenum oxide or tungsten oxide and, deposited thereon, a second layer comprising magnesium.

This application is a 371 nationalization of international patent application PCT/EP2020/057526 filed Mar. 18, 2020, which claims priority under 35 USC § 119 to German patent application DE 10 2019 107 163.1 filed Mar. 20, 2019. The entire contents of each of the above-identified applications are hereby incorporated by reference.

### BRIEF DESCRIPTION OF THE DRAWINGS

In the drawings:

FIG. 1 is a schematic sectional illustration of a thin-film transistor;

FIG. 2 is a schematic sectional illustration of a thin-film transistor according to the invention;

FIGS. 3a, 3b show transistor characteristic curves of the thin-film transistor from FIG. 2;

FIG. 4 is a schematic sectional illustration of an alternative thin-film transistor according to the invention; and

FIGS. 5a, 5b show transistor characteristic curves of the thin-film transistor from FIG. 4.

### DESCRIPTION

The invention relates to a thin-film transistor in which as many system elements as possible, such as gate, source or drain electrodes, comprise biodegradable, bioresorbable and/or biocompatible materials. Furthermore, the invention comprises a method for producing a thin-film transistor of this kind. A thin-film transistor of this kind is suitable for use in absorbable implants or other components which are intended to decompose in a biological environment in such a way that no retrieval of the entire component from the place of use is required.

Thin-film transistors consist of the system elements electrodes (gate, source, and drain electrode), gate insulator and semiconductor, which are usually applied to a substrate. Since the gate insulator and the semiconductor are usually applied in layers during the production process of a thin-film transistor, these system elements of a thin-film transistor are subsequently also used as an insulator layer or referred to as a semiconductor layer. There are numerous examples where single or multiple system elements of a thin-film transistor are made from materials designated as biodegradable, bio-based, bioresorbable, or green. An exact meaning of these feature terms is usually not explicitly defined. Often the material properties related to this are not known with certainty either, but it is indirectly concluded that certain features can be assumed for a material under consideration. Research typically demonstrates the manufacturability and functionality of new materials in thin-film transistors in order to pursue specific application goals, such as the applicability in resorbable implants in accordance with the certification regulations for medical products or the biodegradability in the sense of a specific standard, such as EN 13432.

In known thin-film transistors, metals from the group of chemical elements Al, Ag, Ti, Cr, Mo, W, Ta, Au, Pd, Pt, Ni are usually used as electrode materials. In addition, carbon nanotubes, graphene, oxides, or organic conductive materials (PEDOT:PSS) can also be used. For the application goal of a bioresorbable implant, metals such as the elements Mg, Fe, Z, W, Ca are considered suitable as well as alloys based on these metals as the main constituent (Zheng, Y. F. et al., Biodegradable metals, Materials Science and Engineering, Vol. 77, 2014, p. 1). However, these metals have so far rarely been used as electrode materials in thin-film transistors.

One difficulty here is that, for use as a source or drain electrode, there should be a Schottky barrier that is as small as possible to the semiconductor material used. Therefore, the work function of an electrode material should correspond to a conveyor belt level (conduction or valence band) of the semiconductor material. An easily biodegradable metal from the group of the above-mentioned chemical elements is typically non-precious and has a relatively small work function and thus a high Fermi level. Therefore, when using these materials as a source or drain electrode, a small Schottky barrier is typically formed not to the valence band (p-type TFT) but to the conduction band (n-type TFT). However, an n-type TFT is much more unstable with respect to environmental influences (oxygen, water) than a p-type TFT.

A further difficulty in the use of biodegradable metals as transistor electrodes lies in their sometimes very poor adhesive properties on biodegradable substrate, insulator or semiconductor materials. For example, the adhesion of Mg on the biodegradable substrate material polylactic acid is very poor when deposited by thermal evaporation in a high vacuum (Hoffmann M., Conductor structures for biodegradable electronics, Coating International, 2017, pp. 23-25).

From Benson N. et al., Complementary organic field effect transistors by ultraviolet dielectric interface modification, Applied Physics Letters, Vol. 89, 2006, p. 182105, it is known to use the chemical element Ca as electrode material in conjunction with the semiconductor material pentacene. However, the functionality of this material combination is only presented in connection with an n-type TFT. Furthermore, the materials of other transistor components, such as components comprising the chemical elements Si, SiO₂ or comprising polymers such as PMMA and PVP, are not biodegradable.

Various biodegradable materials such as silk, shellac, gelatin, caramelized glucose, or albumin are known for use as gate insulators in thin-film transistors. In Bettinger Ch. J., et al., Organic Thin-Film Transistor Fabricated on Resorbable Biomaterial Substrates, Advanced Materials, Vol. 22, 2010, pp. 651-655, it is further proposed to use polyvinyl alcohol for this purpose.

Biodegradable materials are also available for the semiconductor of a thin-film transistor. In the target application of a completely degradable thin-film transistor, a process temperature that is as low as possible is generally important, since, in particular, degradable substrate materials are less temperature-stable compared to typical non-degradable substrate materials. Therefore, organic semiconductor materials are particularly suitable for a biodegradable thin-film transistor.

In Irimia-Vladu M., “Green” electronics: biodegradable and biocompatible materials and devices for sustainable future, Chemical Society Reviews, Vol. 43, 2014, pp. 588-610, various organic semiconductor materials are named which are either directly of natural origin or are chemically closely related to such natural materials (“nature-inspired”). A material named herein from the group of natural or nature-inspired organic semiconductors is quinacridone (CI Pigment Violet 19). The cytotoxicity of quinacridone for use within a body was, for example, tested and found negative in Sytnyk M. et al., Cellular interfaces with hydrogen-bonded organic semiconductor hierarchical nanocrystals, Nature Communications, Vol. 8, no. 91, 2017, pp. 1 to 11.

Quinacridone-based thin-film transistors are described in Glowacki E. D. et al., Hydrogen-Bonded Semiconducting Pigments for Air-Stable Field-Effect Transistors, Advanced Materials, Vol. 25, 2013, pp. 1563-1569. However, the non-degradable materials used for the electrodes are silver or gold, for the substrate glass, and for the gate insulator aluminum oxide.

Furthermore, thin-film transistors in which the substrates consist of biodegradable materials such as silk, shellac, gelatin, collagen, chitin, chitosan, alginate, or dextran are also known. In addition, thin-film transistors in which the substrate is formed from the biodegradable material poly(lactide-co-glycolide), abbreviated as PLGA, (Bettinger Ch. J., et al., Organic Thin-Film Transistor Fabricated on Resorbable Biomaterial Substrates, Advanced Materials, Vol. 22, 2010, pp. 651-655), are also known. However, it is proposed to use the non-degradable materials gold or silver for the electrode contacts.

It is also often a disadvantage that not all the components required are biodegradable, as is known, for example, from U.S. Pat. No. 8,666,471 B2.

In summary, it can be stated that although there are suitable biodegradable materials for every system element of a thin-film transistor, no thin-film transistor is known in which all system elements consist of biodegradable materials, because either no functionality in the interaction of biodegradable materials of different thin-film transistor system elements or no sufficient adhesion of the layer materials could be achieved.

The invention is therefore based on the technical problem of creating a thin-film transistor and a method for producing a thin-film transistor by means of which the disadvantages of the prior art can be overcome. In particular, a thin-film transistor electrode according to the invention has biodegradable materials and the method according to the invention makes a thin-film transistor of this kind possible. Furthermore, in the case of a thin-film transistor according to the invention, it should be possible to make up all system elements from biodegradable or non-cytotoxic materials.

Surprisingly, it has been found that magnesium can be used as a material for the electrodes of a thin-film transistor when a layer of molybdenum oxide or tungsten oxide is previously applied to a substrate used or to a semiconductor material used.

A thin-film transistor according to the invention therefore comprises a substrate, at least one semiconductor layer, at least one insulator layer, at least one source electrode, at least one drain electrode, and at least one gate electrode, wherein the at least one source electrode and/or the at least one drain electrode and/or the at least one gate electrode consist(s) of a layer system which includes a first layer comprising molybdenum oxide or tungsten oxide and a second layer comprising magnesium deposited thereon. As alternatives to molybdenum oxide or to tungsten oxide, the materials vanadium oxide and nickel oxide are also conceivable for the first layer. Alternatively, iron or zinc can also be deposited as a second layer.

Particularly advantageous is a thin-film transistor according to the invention in which the at least one source electrode and/or the at least one drain electrode and/or the at least one gate electrode consist(s) of a layer system which comprises a first layer of molybdenum oxide and a second layer of magnesium deposited thereon. If a molybdenum oxide layer is firstly deposited and a magnesium layer is subsequently deposited, both a high adhesive strength of the magnesium layer and an efficient hole injection into the valence band of an organic semiconductor arranged under the molybdenum layer for a p-like field effect transistor can be achieved. The electrode material according to the invention for a thin-film transistor, comprising a first layer of molybdenum oxide and a second layer of magnesium deposited thereon, can preferably be used in thin-film transistors in which the semiconductor material consists of an organic semiconductor material. Such materials can be, for example, pentacene or quinacridone. Alternatively, the electrode material according to the invention can also be used in thin-film transistors in which the semiconductor material consists of an inorganic semiconductor material.

In an embodiment of a thin-film transistor according to the invention, the insulator layer consists of poly(4-vinylphenol), hereinafter also referred to as PVP.

The insulator layer and/or the substrate can alternatively also consist of an inorganic organic hybrid polymer, as is known, for example, from EP 1 803 173 B1, and preferably of a biodegradable inorganic-organic hybrid polymer, which are described, for example, in DE 10 2016 107 760 A1 and WO 2016/037871 A1.

Thus, biodegradable inorganic-organic hybrid polymers can be produced, for example, by crosslinking and curing a silane resin or a silane resin mixture by means of UV radiation. In one embodiment of the invention, at least one more crosslinking agent is added to the silane resin or the silane resin mixture before curing by means of UV radiation. For example, commercially available crosslinking agents can be used as crosslinking agents.

A biodegradable inorganic-organic hybrid polymer of this kind can be formed, for example, by silanes of the formula (1):

R¹ₐSiR₄₋ₐ (1),

wherein the silanes preferably have several substituents R¹ per silicon atom, which, generally, are made up exclusively of organic components and are bonded to the silicon via oxygen. Each of these substituents R¹ has a hydrocarbon-containing chain of variable length (straight-chain or branched, preferably ring-free) which is interrupted by at least two, preferably at least three —C(O)O groups. In the individual hydrocarbon units formed by the interruptions, a maximum of 8, preferably not more than 6, and more preferably not more than four carbon atoms, follow one another within this chain, wherein the chain is interrupted by oxygen and/or sulfur atoms. In addition, the end of the hydrocarbon-containing chain facing away from the silicon atom or—in the case of branched structures—at least one (preferably each) of these ends has an organic polymerizable group, which is generally selected from groups containing an organically polymerizable C═C double bond, preferably acrylic or, more preferably, methacrylic groups, in particular acrylate or, more preferably, methacrylate groups, and ring-opening systems such as epoxides. The organic polymerization may be a polyaddition. This can be induced photochemically, thermally or chemically (2-component polymerization, anaerobe polymerization, redox-induced polymerization). The combination of self-hardening, for example, by means of photo-induced or thermal hardening, is also possible.

The hydrocarbon chain can also be interrupted by oxygen atoms (ether groups) or sulfur atoms (thioether groups). The hydrocarbon units located between the ether, thioethers, or ester groups are preferably alkyl units and may be substituted with one or more substituents which are preferably selected from hydroxy, carboxylic acid, phosphate, phosphonic acid, phosphonic acid ester, and (preferably primary or secondary) amino and amino acid groups. The index a in these silanes is selected from 1, 2, 3, or 4, wherein the silanes of the formula (1) are, generally, present as mixtures of silanes having different meanings of the index a and this index in the mixture often has an average value of about 2. R is a hydrolytically condensable group and preferably selected from groups with the formula R^{I}COO—, but can also be OR^{I} or OH, where R^{I} is alkyl and preferably methyl or ethyl.

The materials will be explained in more detail below on the basis of a schematic representation of a silane of the formula (1). One of the substituents R¹ is shown, bound to the silicon atom via an oxygen atom. This oxygen atom is part of a polyethylene glycol group with n ethylene glycol units and thus n alkyl groups with two carbon atoms each. The last of these units is esterified with ethylene dicarboxylic acid, the second carboxylic acid unit of which is in turn esterified with (here optionally with any sub stituent R^{II}, which in particular can be CH₃, COOH or CH₂OH) ethylene glycol, the second OH group of which was esterified with methacrylic acid, ultimately producing a derivative of 4-[2-(methacryloyloxy)ethoxy]4-oxo-butanoic acid (MES). This means that the group (except for the branching possibly caused by R^{II}) is unbranched and has a methacrylic group at its end facing away from the silicon atom, which methacrylic group can be organically polymerized via its C═C double bond. It should be mentioned that the substituent R^{II} is only given as an example in this schematic representation; of course, such substituents can also be present at any other desired locations.

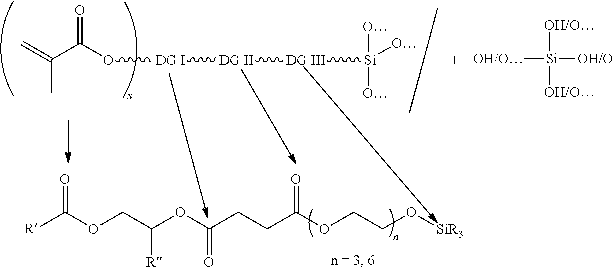

The two carboxylic acid ester groups present in this group are amenable to hydrolysis and are denoted here by DG I and DG II. The ester bond between the methacrylic acid and the ethylene glycol, which may be substituted with R^{II}, can also be cleaved hydrolytically. Cleavage on “DG III”, the Si—O bond, also occurs under hydrolysis conditions. Thus, a material is provided which can also be degraded to the silicon at the coupling point of the organic group. Furthermore, in some constellations, polyether groups can be cleaved oxidatively in vivo.

It can be seen from the above-mentioned explanations that, in hydrolytic degradation, the provision of only short hydrocarbon chains interrupted by oxygen atoms, sulfur atoms, or ester groups (—C(O)O—) largely leads to small-molecule products which, generally, are physiologically harmless as such. In the above example, succinic acid and a crosslinked polymethacrylic fragment are formed, which is also toxicologically harmless due to its crosslinking. Depending on the crosslinking conditions, the latter, generally, also has a relatively low molecular weight, since the silane molecules are already relatively rigid to one another due to the preceding hydrolytic condensation, which is why a higher-level crosslinking of an uninterrupted plurality of methacrylate groups is rather unlikely. If materials are used which have additional OH or COOH substituents or the like on the respective hydrocarbon chains, molecules may be produced which occur in the human body as intermediates, such as lactic acid or citric acid, so that they could be introduced into its metabolism. The remaining, essentially inorganic residues are essentially fragments with Si—O—Si linkages, which are covered with hydroxy groups on the outside. Hydrolysis and condensation of the above-mentioned silane of the formula (1) with R=OAc, i.e., CH₃C(O)O) produces a resin which is an organically modified silica polycondensate.

The substitution of silicon with two of the organic substituents R¹ in question is an average value; the starting “silane” for the resin consists, generally, of a mixture of different silanes in which partly none, partly one, two, three, or four of these organic groups are bound to a silicon atom, wherein on average two of the organic groups per silicon atom are present. The number of OAc (acetyl) groups on the silicon is also a statistical value. The acetyl groups originate, for example, from the starting material silicon tetraacetate and are retained even under hydrolytic conditions in approximately the above-mentioned proportion. The hydroxy groups formed by hydrolysis of OAc groups are converted into Si—O—Si bridges under the conditions of hydrolytic condensation.

The number of organically polymerizable C═C double bonds per substituent R¹ can also greatly influence the mechanical properties: If this substituent is branched and the two branching ends each contain an organically polymerizable C═C double bond, the values for the tensile elongation and the E modulus increase by more than a power of ten.

It can thus be seen that, when an inorganic-organic hybrid polymer is used as a substrate or as a gate insulator, a specifically sought-after adaptation of the mechanical properties of the substrate or the substrate of the gate insulator to certain requirements. Since both the inorganic and the organic crosslinking density can be adjusted, a person skilled in the art can achieve precisely the desired values by suitable selection within the parameters.

The crosslinking in the hybrid polymers can also be modified or strengthened. This special form of post-hardening does not use, or uses not only the polymerization reaction of the organically polymerizable groups as such as explained above. If the organic polymerizable groups are C═C double bonds or ring-opening systems such as epoxides, a reaction of the silicic acid polycondensates containing these double bonds with di- or greater amines or di- or greater thiols is also possible via a Michael addition (thiol-ene reaction or the analogous reaction with amines). This is achieved with di-, tri-, tetra- or even more highly functionalized amines or mercaptans (thiols), the reaction with amines in the case of C═C double bonds as organic polymerizable groups being possible if they are in an activated form, for example as acrylic or methacrylic groups. The polymerization of the remaining C═C double bonds or ring-opening systems such as epoxy groups are then carried out as described above. Further possibilities for variation are disclosed in WO 2016/037871 A1.

As a further alternative, the insulator layer and/or the substrate may also consist of a biodegradable inorganic-organic hybrid polymer, wherein the hybrid polymer is formed from a mixture of a crosslinking agent and a silane according to the formula (2) after its hydrolysis/condensation:

R²_{b}SiR_{4.b} (2)

as well as inorganically crosslinked condensates and/or organically crosslinked polymers produced from or according to the formula (2), wherein the group R² or each of the groups R², independently of one another,
is bound to the silicon via an oxygen atom,
has a straight-chain or branched, hydrocarbon-containing chain with one or more elements, which either
   (a) each possess no more than 8 successive carbon atoms, wherein each of several elements of the hydrocarbon-containing chain is separated from the next element by a cleavable group of several elements, and/or (b) has one or more cleavable groups, and all hydrocarbon-containing chains that remain when this/these group(s) is/are cleaved is/are water-soluble, wherein the cleavable groups are selected from ester, anhydride, amide, carbonate, carbamate, ketal, acetal, disulfide, imine, hydrazone, and oxime groups,
has at least one thiol or primary or secondary amino group, the group R or each of the groups R is a group that can be hydrolytically condensed independently from one another, and
   b=1, 2, 3, or 4.

Suitable crosslinking components for mixing with the silane after its hydrolysis/condensation and further possibilities for variation are disclosed in the patent application with the file number DE102018114406.7.

In the method for producing a thin-film transistor according to the invention, comprising a substrate, at least one semiconductor layer, at least one insulator layer, at least one source electrode, at least one drain electrode, and at least one gate electrode, a first layer comprising molybdenum oxide or tungsten oxide is firstly deposited and a second layer comprising magnesium is deposited thereon for forming the at least one source electrode and/or the at least one drain electrode and/or the at least one gate electrode. For example, thermal evaporation of the respective layer material is suitable for depositing the first layer of molybdenum oxide or tungsten oxide and/or the second layer of magnesium.

The invention is described in more detail below on the basis of embodiments.

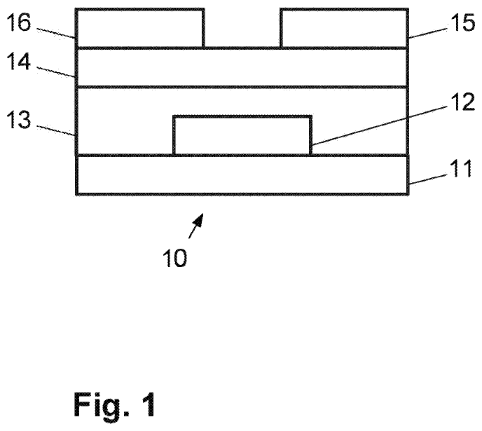

FIG. 1 is a schematic section view of the basic construction of a thin-film transistor 10. The thin-film transistor 10 comprises a substrate 11, on which an electrically conductive and laterally structured layer for a gate electrode 12 is firstly deposited. An insulator layer 12 comprising an electrically insulating material, a semiconductor layer 14 comprising a semiconductor material, and a laterally structured layer comprising an electrically conductive material from which a drain electrode 15 and a source electrode 16 are formed are deposited thereon.

For the embodiment according to FIG. 1, the following layer materials and deposition methods are used:

The gate electrode 12 is formed on the glass substrate 11 by thermal evaporation of aluminum in a high vacuum. The lateral structure of the gate electrode 12 is formed by means of a shadow mask arranged between the substrate and a coating source. Poly(4-vinylphenol) is applied to the gate electrode 12 by means of a rotary coating, then crosslinked by heating and, thus, the insulator layer 13 is formed. The semiconductor layer 14 is deposited on the insulator layer 13 by thermal evaporation of pentacene when the substrate 11 is heated.

In an experiment, the drain electrode 15 and the source electrode 16 of magnesium was intended to be formed on the semiconductor layer 14. To this end, magnesium was thermally evaporated, and a shadow mask was again arranged between substrate 11 and a magnesium coating source in order to structure the electrodes laterally. After the coating process, only a semitransparent gray layer could be detected with the naked eye in the surface regions in which the drain electrode 15 and the source electrode 16 were to be deposited, which is an expression of the fact that magnesium merely forms insufficient adhesion to pentacene. It was not possible to determine any transverse conductivity by means of four-tip measurement technology in these regions either, as a result of which it was demonstrated that magnesium is not suitable for deposition on pentacene for the formation of transistor electrodes.

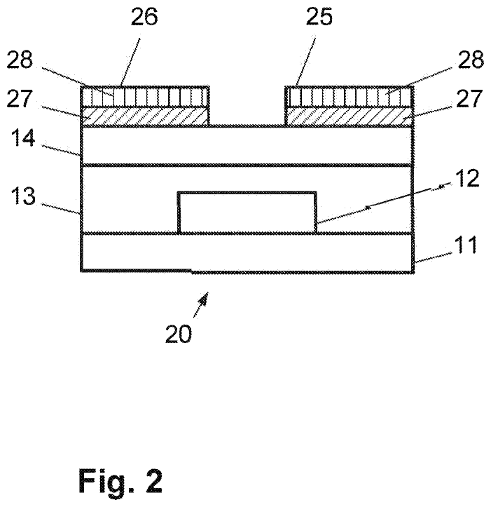

FIG. 2 is a schematic section view of a thin-film transistor 20 according to the invention. The thin-film transistor 20, like the thin-film transistor 10 from FIG. 1, comprises a substrate 11, a gate electrode 12, an insulator layer 13, and a half-layer 14, which consist of the same material and have been deposited by the same methods as the elements from FIG. 1 with the same reference signs.

According to the invention, however, a drain electrode 25 and a source electrode 26 were formed from pentacene on the semiconductor layer 14 by firstly depositing a laterally structured first layer T1 comprising molybdenum oxide and depositing a laterally structured second layer 28 comprising magnesium thereon. The first layer T1 and the second layer 28 were deposited by thermal evaporation of the respective layer material in a high vacuum through a shadow mask. After the deposition process, metallic layers could be visually identified by the naked eye in the regions of the drain electrode 25 and the source electrode 26, as they are also produced in the case of magnesium deposition on glass. The cross-conductivity showed, in the regions of the drain electrode 25 and the source electrode 26, a layer resistance of about 0.4 ohm/sq at 200 nm magnesium layer thickness. This corresponds with the value as in a magnesium deposition on glass. The absolute value is greater by a factor of 1.8 than would correspond with the nominal bulk conductivity of magnesium. This measured cross-conductivity thus confirms the typical behavior of a metal thin-film relevant to electrode applications.

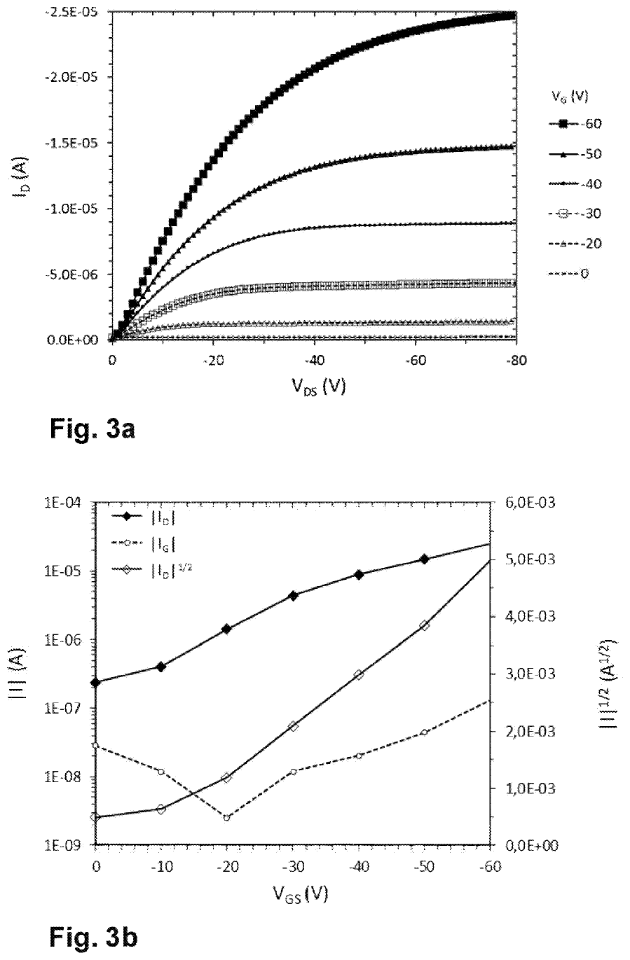

FIGS. 3a and 3b show the transistor characteristic curves for the embodiment described in FIG. 2. At the same time, FIG. 3a shows the output characteristic curve field. The uppermost, first curve with the filled quadrangles, shows the pairs of values at a gate voltage of −40 V, the second, underlying curve, with the filled triangles, shows the pairs of values at a gate voltage of −35 V, the third curve shows the pairs of values at a gate voltage of −30 V, the fourth curve shows the pairs of values at a gate voltage of −25 V, the fifth curve shows the pairs of values at a gate voltage at −20 V, the lowest, sixth curve with small filled circles shows the pairs of values at a gate voltage of 0 V. FIG. 3b is a transmission characteristic curve l_{D}(V_{GS}), derived from the output characteristics at U_{DS}=−80 V, shown in semi-logarithmic representation (solid line with filled rhombus symbol, left axis) and as a root representation (solid line with open rhombus symbol, right axis). In addition, the respective gate leakage current l_{G}(V_{GS}) (dotted line with unfilled circle, left axis) is shown semi-logarithmically. The extracted saturation mobility is 0.2 cm²/(V_{S}) at −50 V.

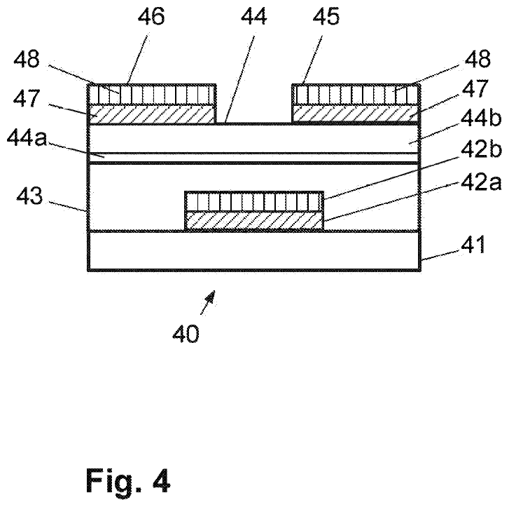

FIG. 4 is a schematic section view of an alternative thin-film transistor 40 according to the invention. The thin-film transistor 40 includes a substrate 41 comprising a biodegradable inorganic-organic hybrid polymer.

As has already been stated above, a biodegradable inorganic-organic hybrid polymer of this kind can be produced by, for example, crosslinking and curing a silane resin mixture by means of UV radiation or at least still mixed with a crosslinking agent and then cross-linked and cured by means of UV radiation. Some embodiments of how a silane resin mixture of this kind can be produced are shown below.

### Embodiment—Resin Variant 1 (Known from WO 2016/037871 A1)

The resin variant 1 is based on a silane of the above-mentioned formula (1) which has the following structure:

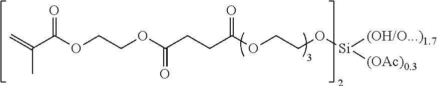

For the preparation of resin variant 1, 10.37 g of silicon tetraacetate are mixed with 36.40 g of 4-[2-(methacryloyloxy)ethoxy]-4-oxo-butanoic acid-triethylenglycolester (abbreviated as MES-TEG) containing about 15 mol. % of disubstituted by-product MES₂TEG. This corresponds with a proportion of MES-TEG of 28.44 g. This mixture is firstly stirred at room temperature for one minute and then heated to 50° C. at 15 mbar for 3 h. The product is then freed of volatile constituents in an oil pump vacuum for 8 h and filtered with the aid of compressed air via a filter with a pore size of 30 μm.

The resulting mixture is then hydrolyzed at 30° C. in several steps. To this end, the mixture is, in each case, mixed with 100 μl of water, stirred for 5 min, freed from volatile constituents in an oil pump vacuum for 5 h, and stirred further until the next interval. The degree of hydrolysis of the Si-OAc and Si-OAlk groups can be checked in each case by means of ¹H-NMR. The addition of water is repeated until the remaining acetate content and the alcohol hydrolysis are as low as possible. In this procedure, about 34 g of the resin variant 1 are produced.

### Embodiment—Resin Variant 2 (Known from WO 2016/037871 A1)

The resin variant 2 is also based on a silane of the above-mentioned formula (1), which has the following structure:

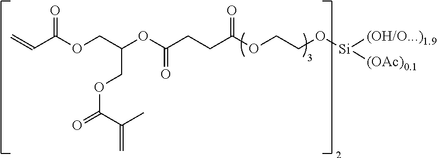

For the preparation of resin variant 2, 7.91 g of silicon tetraacetate are reacted with 40.13 g of 4-{1,3-bis [(methacryloyl)oxy]propan-2-yloxy}-4-oxo-butanoic acid-triethylenglycolester (abbreviated as GDM-SA-TEG), which contain approximately 20 mol. % disubstituted by-product (proportion of GDM-SA-TEG: 28.29 g). The product is then freed from volatile components and pressure-filtered.

As explained above in the synthesis of the resin system 1, the hydrolysis/condensation takes place step by step at 30° C. and can be controlled by means of ¹H-NMR. This results in approximately 32 g of the resin variant 2.

### Embodiment—Resin Variant 3 (Known from WO 2016/037871 A1)

Resin variant 3 is in turn based on a silane of the above-mentioned formula (1), which has the following structure:

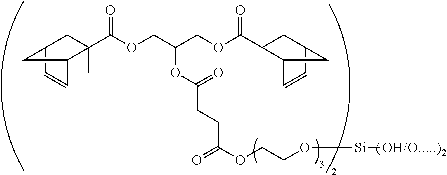

For the preparation of the resin variant 3, 20 g of resin variant 2 is dissolved in 80 mg of butylhydroxytoluene. The reaction mixture is then stirred at 90° C. and cyclopentadiene is slowly added. The cyclopentadiene is prepared in parallel through the thermal cleavage of dicyclopentadiene and transferred to the reaction mixture by distillation. The conversion of the acrylate and methacrylate group can be monitored by ¹H-NMR spectroscopy. After completion of the reaction, unreacted cyclopentadiene and dicyclopentadiene are removed from the reaction mixture under reduced pressure.

### Embodiment—Resin Variant 4

The resin variant 4 is based on a silane of the above-mentioned formula (2). For this purpose, a compound HS—CH(CH₃)—CH(CH₃)—OH (hereinafter also referred to as S1) with silicon tetraacetate to form a silane takes place, which can also be illustrated as follows:

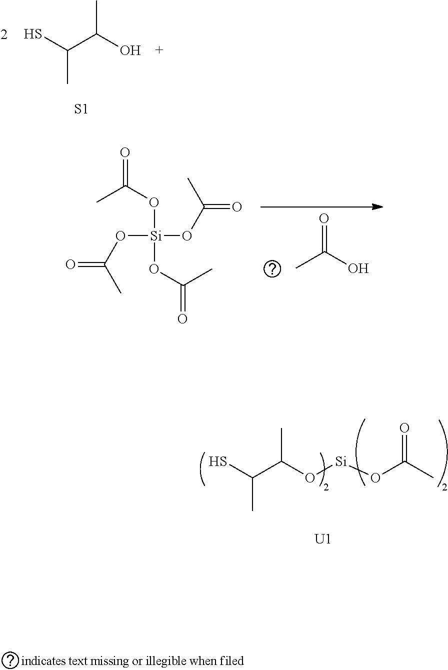

Specifically, 37.33 g of silicon tetraacetate are mixed with 30.00 g of the component 2-mercapto-3-butanol designated as S1. The resulting reaction mixture is first stirred for one minute at room temperature and then heated to 50° C. at 15 mbar for 1.5 h. The pressure is then reduced to 1 mbar for a further 1.5 h. The reaction mixture is freed of volatile components in an oil pump vacuum for 8 h and filtered with the aid of compressed air via a filter having a pore size of 15 μm. In the resulting product mixture, which is referred to above as U1, an average of two alkoxy groups and two acetoxy groups are bonded to one silicon atom. In the procedure described, about 50 g of the product mixture U1 are achieved.

The product mixture U1 is then hydrolyzed in several steps at 90° C. To this end, enough water is added that one water molecule (but at least every twentieth acetate group present before hydrolysis) is added to every fifth remaining acetoxy group. After the addition of water, the mixture is stirred at 90° C. for one minute and then the volatile components are removed in an oil pump vacuum. The degree of hydrolysis of the Si-OAc and the Si-OAlk groups can be checked in each case by means of ¹H-NMR spectroscopy. The addition of water is repeated until essentially all acetate groups have been removed from the mixture. No cleavage of the alkoxy groups was observed in such a procedure. In the case of the resulting end products, an average of two alkoxy groups are bound to a silicon atom.

The above-described silane resin mixtures according to resin variants 1 to 4 can be used as starting material for the production of biodegradable inorganic-organic hybrid polymers, which can be used as a substrate and/or as an insulator layer in a thin-film transistor according to the invention.

In the embodiment described in FIG. 4, a silane resin mixture according to the resin variant 4 is used as the starting material for the production of the substrate 41. Here, 40.3 wt. % of the silane resin mixture according to resin variant 4, 58.5 wt. % of a crosslinking agent, 0.2 wt. % of pyrogallol, and 1 wt. % of 2,4,6 trimethylbenzoyldiphenylphosphine oxides are mixed together, then filled into a PET casting mold and the casting mold is covered with a glass plate and pressed. Subsequently, the substance filled into the casting mold is photochemically cured on both sides for 130 s. After the removal of the PET film and the glass plate, a transparent and flexible substrate 41 is present from a biodegradable, inorganic-organic hybrid polymer. The layer thickness of a substrate produced in this way is between 90-125 μm.

For the preparation of a crosslinking agent which is mixed with a silane resin mixture, it is possible, for example, to dissolve 0.012 g of butyl hydroxytoluene in 30.00 g of glycerol acrylate methacrylate. The reaction mixture is then stirred at 80° C. and cyclopentadiene is slowly added. The cyclopentadiene is produced in parallel by the thermal cleavage of dicyclopentadiene and transferred to the reaction mixture by distillation. The conversion of the acrylate group and methacrylate group can be monitored by ¹H-NMR spectroscopy. After completion of the reaction, unreacted cyclopentadiene and dicyclopentadiene are removed from the reaction mixture under reduced pressure.

According to the invention, a gate electrode is formed on the substrate 41 by depositing a first layer 42a of molybdenum oxide and then a second layer 42b of magnesium on the substrate 41. The two layers are deposited by thermal evaporation of the respective layer material under vacuum conditions through a shadow mask. The adhesion of the layer sequence for forming a gate electrode on a hybrid polymer substrate can be further improved if the hybrid polymer substrate is pretreated with an oxygen plasma before the layer deposition. For example, an ion source can be used to produce an oxygen plasma of this kind. In the embodiment described in FIG. 4, a linear ion source was used which generates a linear ion beam on the substrate 41 at an acceleration voltage of 1 keV, while the substrate 41 is moved in an in-line configuration by the ion beam. In optimization tests with regard to the transistor properties, it was also found that a plasma pretreatment of the substrate causes a slight improvement in the gate leakage currents of a transistor.

After the formation of the gate electrode, an insulator layer 43 is deposited by means of a silane resin mixture according to the resin variant 3 in conjunction with the commercially available crosslinking agent trimethylolpropane tri(3-mercaptopropionate) (in the molar ratio of C═C:SH=1:0.9), is applied by means of a rotational coating in a period of one minute. Before the rotational coating, however, the silane resin mixture was dissolved in acetone with a mass fraction of 10%. After the rotational coating, the substrate 41 is heated for 30 minutes at 65° C. on a heating plate and then exposed to approx. 70 mW/cm² of UV-A intensity with a UV radiator (an iron-doped mercury vapor lamp was used in the embodiment) for 400 s, as a result of which the layer material is crosslinked. The insulator layer 43 thus also consists of a biodegradable, inorganic-organic hybrid polymer.

For the purpose of forming a semiconductor 44, a buffer layer 44a comprising tetratetracontan and then a layer 44b comprising quinacridone are applied to the insulator layer 43 by thermal evaporation of the respective layer material under vacuum conditions, wherein the substrate 41 is heated after the depositing of the buffer layer 44a for 12 h at 60° C. in a nitrogen furnace.

According to the invention, the formation of a drain electrode 45 and a source electrode 46 also takes place by firstly depositing a laterally structured first layer 47 comprising molybdenum oxide and depositing a laterally structured second layer 48 comprising magnesium thereon. The first layer 47 and the second layer 48 are deposited by thermal evaporation of the respective layer material in a high vacuum through a shadow mask. After the deposition process, metallic layers which had a layer resistance of 0.5-1 Ohm/sq could also be visually identified by the naked eye in the regions of the drain electrode 45 and the source electrode 46.

The thin-film transistors produced according to the invention, according to the embodiment described in FIG. 4, show a normal transistor behavior with saturation mobilities of the order of magnitude of 0.01 cm²/(V_{S}). This result proves the effectiveness of a molybdenum intermediate layer as an effective hole injection layer also for the magnesium-quinacridone interface.

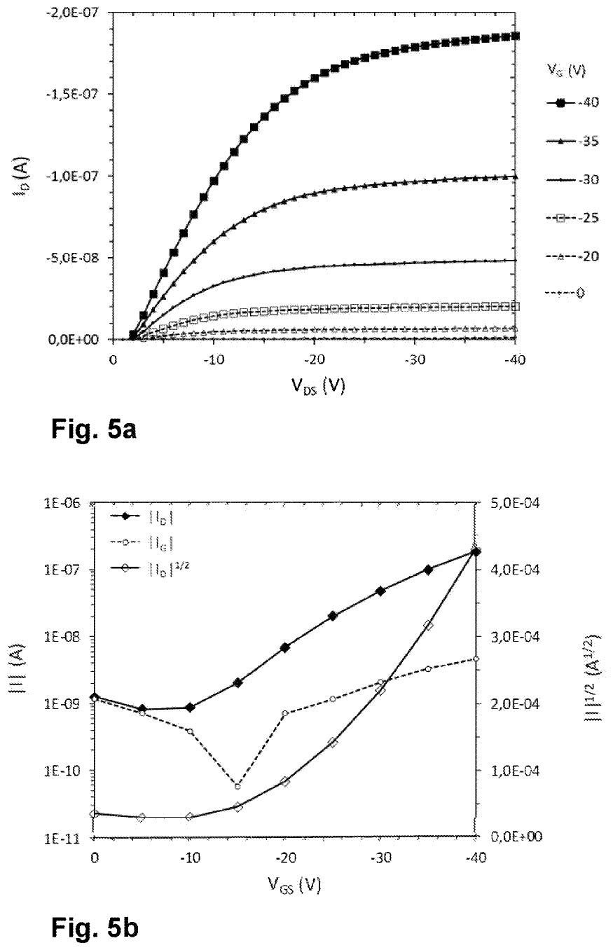

FIGS. 5a and 5b show the transistor characteristic curves for the embodiment described in FIG. 4. At the same time, FIG. 5a shows the output characteristic curve field. Here, the curves from top to bottom show the pairs of values for the gate voltages −40 V, −35 V, −30 V, −25 V, −20 V and 0 V. In FIG. 5b is a transmission characteristic curve l_{D}(V_{GS}), derived from the output characteristic curves at UDS=−80 V, in a semi-logarithmic representation (solid line with a filled rhombus symbol, left axis) and as a root representation (solid line with unfilled rhombus symbol, right axis). In addition, the respective gate leakage current l_{G}(V_{GS}) (dotted line with unfilled circle, left axis) is shown semi-logarithmically. Extracted saturation mobility is 0.015 cm²/(V_{S}) at −35 V.

With the example described in FIG. 4, there are thin-film transistors in which all transistor materials are either biodegradable or at least not cytotoxically effective. A thin-film transistor of this kind according to the invention can be used, for example, for the production of a component which is implanted or inserted as a biodegradable implant in an animal or human body.

It should be noted that the process parameters described in the embodiments for layer deposits and mixture compositions of biodegradable inorganic-organic hybrid polymers used are merely exemplary and do not limit the scope of the invention thereto.

To clarify the use of and to hereby provide notice to the public, the phrases “at least one of <A>, <B>, . . . and <N>” or “at least one of <A>, <B>, . . . or <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed. Unless otherwise indicated or the context suggests otherwise, as used herein, “a” or “an” means “at least one” or “one or more.”

1. A thin-film transistor, comprising at least one semiconductor layer, at least one insulator layer, at least one source electrode, at least one drain electrode, and at least one gate electrode, which are arranged on a substrate, wherein the at least one source electrode and/or the at least one drain electrode and/or the at least one gate electrode consist(s) of a layer system which comprises a first layer comprising molybdenum oxide or tungsten oxide and a second layer comprising magnesium deposited thereon.

2. The thin-film transistor according to claim 1, wherein the at least one semiconductor layer comprises an organic material.

3. The thin-film transistor according to claim 2, wherein the at least one semiconductor layer contains pentacene.

4. The thin-film transistor according to claim 2, wherein the at least one semiconductor layer contains quinacridone.

5. Thin-film transistor according to any of claim 1, wherein the at least one insulator layer contains poly(4-vinylphenol).

6. Thin-film transistor according to claim 1, wherein the at least one insulator layer and/or the substrate comprises an inorganic-organic hybrid polymer.

7. Thin-film transistor according to claim 6, wherein the hybrid polymer is obtainable by reacting a silane of formula (1)
R¹ₐSiR_{4.a} (1),
wherein the group R¹ or each of the groups R¹, independently of one another,
is bound to the silicon via an oxygen atom,
is a straight-chain or branched, hydrocarbon-containing chain which is interrupted by at least two —C(O)O groups and where a maximum of 8 carbon atoms follow one another in the hydrocarbon units formed by the interruptions,
R is a hydrolytically condensable group of the formula R^{I}COO—, where R^{I} means alkyl, and
a=1, 2, 3, or 4.

8. Thin-film transistor according to claim 7, wherein the hybrid polymer comprises a crosslinking agent.

9. Thin-film transistor according to claim 6, wherein the hybrid polymer is a reaction of a mixture consisting of a crosslinking agent and a silane of the formula (2) after its hydrolysis/condensation:
R²bSiR4-b (2),
wherein the group R² or each of the groups R², independently of one another,
is bound to the silicon via an oxygen atom,
has a straight-chain or branched, hydrocarbon-containing chain with one or more elements, which either
(a) each have no more than 8 carbon atoms following one another, wherein each of several elements of the hydrocarbon-containing chain is separated from the next element by a cleavable group, and/or
(b) has one or more cleavable groups and all hydrocarbon-containing chains that remain when this/these group(s) is/are cleaved are water-soluble, wherein the cleavable groups are selected from ester, anhydride, amide, carbonate, carbamate, ketal, acetal, disulfide, imine, hydrazonyl, and oxime groups,
has at least one thiol or primary or secondary amino group, the group R or each of the groups R is, independently of one another, a hydrolytically condensable group, and
b=1, 2, 3, or 4.

10. A method for producing a thin-film transistor, comprising at least one semiconductor layer, at least one insulator layer, at least one source electrode, at least one drain electrode, and at least one gate electrode, which are arranged on a substrate, wherein, in order to form the at least one source electrode and/or the at least one drain electrode and/or the at least one gate electrode, a first layer comprising molybdenum oxide or tungsten oxide is firstly deposited and a second layer comprising magnesium is deposited thereon.
